(19) United States
(12) Patent Application Publication
(10) Pub. No.: US 2010/0301366 A1
(43) Pub. Date: Dec. 2, 2010

(54) ORGANIC ELECTRO-LUMINESCENCE DEVICE

(76) Inventor: Masashi TAKAHASHI, Ishikawa-gun (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/786,944

(22) Filed: May 25, 2010

(30) Foreign Application Priority Data
May 27, 2009 (JP) 2009-127870

(51) Int. Cl. H01L 51/52

(52) U.S. Cl. 257/98; 257/E51.018

(57) ABSTRACT

According to one embodiment, an organic EL device includes an insulating substrate, an organic EL element including a pixel electrode arranged in an active area above the insulating substrate, an organic layer arranged on the pixel electrode, and an opposed electrode arranged on the organic layer, a wiring arranged in a peripheral area outside the active area above the insulating substrate and electrically connected to the opposed electrode that extends from the active area to the peripheral area, and a conductive layer formed on the opposed electrode in a connection portion that connects the wiring and the opposed electrode.

### CROSS-REFERENCE TO RELATED APPLICATIONS

This application is based upon and claims the benefit of priority from Japanese Patent Application No. 2009-127870, filed May 27, 2009; the entire contents of which are incorporated herein by reference.

### FIELD

Embodiments described herein relate generally to an organic electro-luminescence (EL) device.

### BACKGROUND

Recently, development of display devices that have characteristics of self-luminosity, quick response, wide viewing angle, and high contrast, and capable of achieving low profile and weight saving has been accelerated.

For example, Jpn. Pat. Appln. KOKAI Publication No. 2007-5320 discloses a technique of providing, in a drive circuit portion, a contact portion for allowing contact between a cathode formed on a bump and a wiring, such that a side surface of the bump has a smoothly curved surface, thereby preventing a break in the cathode.

### BRIEF DESCRIPTION OF THE DRAWING

FIG. 1 is a plan view schematically illustrating a configuration of an organic EL device according to an embodiment of the present invention;

FIG. 2 is a schematic cross-sectional view of an array substrate including an organic EL element of an organic EL device according to the embodiment;

FIG. 3 is a plan view of a layout example of a conductive layer shown in FIG. 2;

FIG. 4 is a plan view of another layout example of the conductive layer shown in FIG. 2;

FIG. 5 is a plan view of another layout example of the conductive layer shown in FIG. 2; and

FIG. 6 is a plan view of another layout example of the conductive layer shown in FIG. 2.

### DETAILED DESCRIPTION

In general, according to one embodiment, an organic EL device comprises an insulating substrate; an organic EL element including a pixel electrode arranged in an active area above the insulating substrate, an organic layer arranged on the pixel electrode, and an opposed electrode arranged on the organic layer; a wiring arranged in a peripheral area outside the active area above the insulating substrate and electrically connected to the opposed electrode that extends from the active area to the peripheral area; and a conductive layer formed on the opposed electrode in a connection portion that connects the wiring and the opposed electrode.

Hereinafter, an embodiment of the present invention will be described in detail with reference to the accompanying drawings. In the descriptions that follow, structural elements that exhibit the same or similar functions will be denoted by the same reference numerals, and a detailed explanation of such elements will be omitted.

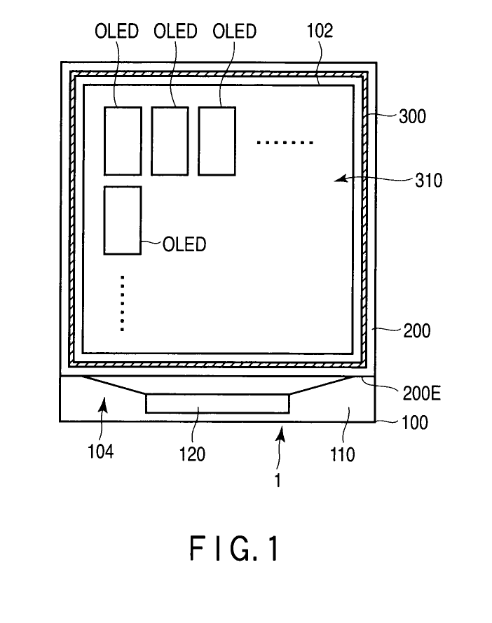

FIG. 1 is a plan view schematically illustrating the configuration of an organic EL device according to an embodiment.

That is, the organic EL device comprises a display panel 1. The display panel 1 comprises an array substrate 100 and an opposed substrate 200. The array substrate 100 comprises a plurality of organic EL elements OLED arranged in a matrix pattern in an approximately rectangular active area 102, designed to display images. The opposed substrate 200 faces an organic EL element OLED of the array substrate 100 in the active area 102. The opposed substrate 200 is an insulating substrate having light transparency, such as one made of glass or plastic.

The array substrate 100 and the opposed substrate 200 are sealed by a frame-shaped sealing member 300 surrounding the active area 102. The sealing member 300 is formed of an organic material, such as ultraviolet-cured resin, or flit glass. When the sealing member 300 is formed of an organic material, a resin layer may be filled into the interior surrounded by the sealing member 300 between the array substrate 100 and the opposed substrate 200. In this case, the resin layer to be filled in may be formed of an organic material having light transparency, such as an ultraviolet-cured resin.

Further, the array substrate 100 comprises an extending portion 110, which extends outward from an end portion 200E of the opposed substrate 200 in a peripheral area 104, provided outside the active area 102. A driving portion 120 is provided in the extending portion 110. A signal supply source, such as a driving IC chip and a flexible printed circuit (hereinafter referred to as an FPC) supplies signals necessary for driving an organic EL element OLED, including a power source and various control signals, to the organic EL element OLED.

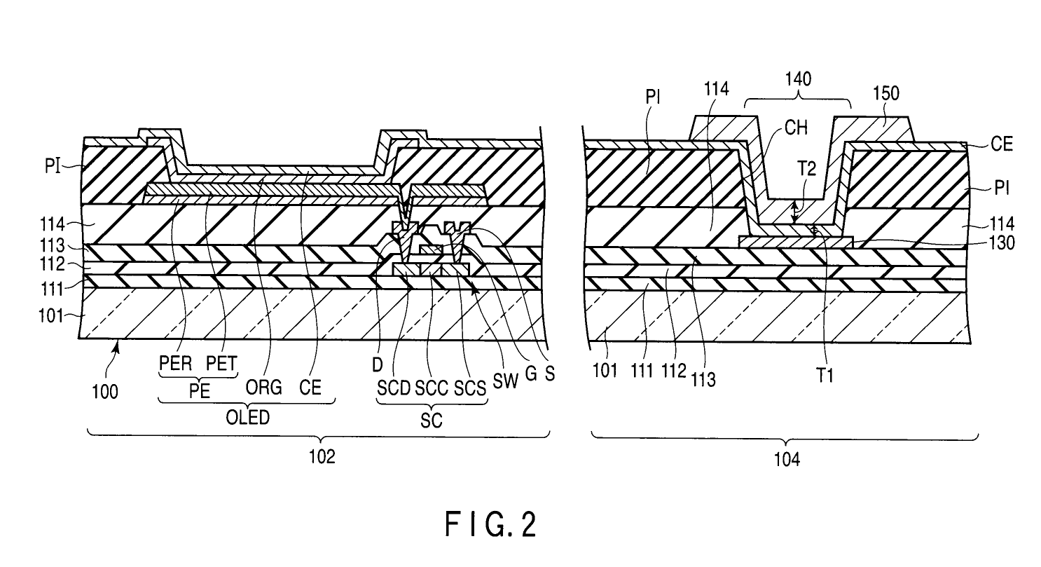

FIG. 2 is a cross-sectional view of the array substrate 100 comprising the organic EL element OLED of the organic EL device according to an embodiment.

The array substrate 100 comprises an insulating substrate 101 made of glass, for example, a switching element SW formed above the insulating substrate 101, and an organic EL element OLED. An undercoat layer 111 is arranged above the insulating substrate 101. The undercoat layer 111 is formed of an inorganic material, such as silicon oxide and silicon nitride. The undercoat layer 111 extends approximately over the entire surface of the active area 102.

A semiconductor layer SC of the switching element SW is arranged on the undercoat layer 111. The semiconductor layer SC is formed of polysilicon, for example. In the semiconductor layer SC, a source region SCS and a drain region SCD are formed so as to interpose a channel region SCC.

The semiconductor layer SC is coated with a gate insulation film 112. The gate insulation film 112 is also arranged on the undercoat layer 111. The gate insulation film 112 is formed of an inorganic material, such as silicon oxide and silicon nitride. The gate insulation film 112 extends approximately over the entire surface of the active area 102.

On the gate insulation film 112, a gate electrode G of the switching element SW is arranged directly above the channel region SCC. In this example, the switching element SW is a top gate type p-channel thin-film transistor. The gate electrode G is coated with a passivation film 113. The passivation film 113 is also arranged on the gate insulation film 112. The passivation film 113 is formed of an inorganic material, such as silicon oxide and silicon nitride. The passivation film 113 extends approximately over the entire surface of the active area 102.

A source electrode S and a drain electrode D of the switching element SW are arranged on the passivation film 113. The source electrode S contacts the source region SCS of the semiconductor layer SC. The drain electrode D contacts the drain region SCD of the semiconductor layer SC. The gate electrode G, the source electrode S, and the drain electrode D of the switching element SW are formed using a conductive material such as molybdenum (Mo), tungsten (W), aluminum (Al), and titan (Ti).

The source electrode S and the drain electrode D are coated with an insulating film 114. The insulating film 114 is also arranged on the passivation film 113. The insulation film 114 is formed of organic materials, such as ultraviolet-cured resin or thermoset resin or various inorganic materials. The insulating film 114 extends approximately over the entire surface of the active area 102.

A pixel electrode PE forming an organic EL element OLED is arranged on the insulation film 114. The pixel electrode PE is connected to a drain electrode D of the switching element SW. The pixel electrode PE is equivalent to an anode in this example.

The pixel electrode PE has a two-layered structure in which a reflective electrode PER and a transparent electrode PET are stacked. That is, the reflective electrode PER is arranged on the insulating film 114. Further, the transparent electrode PET is stacked on the reflective electrode PER. The reflective electrode PER is formed of a conductive material having light reflectivity, such as silver (Ag) or aluminum (Al). The transparent electrode PET is formed of a conductive material having light transparency, such as indium tin oxide (ITO) and indium zinc oxide (IZO). The pixel electrode PE is not limited to the above-described two-layered structure and may be a single layer of a reflective electrode PER or a single layer of a transparent electrode PET. When a micro-cavity structure is adopted, the pixel electrode PE includes a reflective electrode PER.

A partition wall PI is arranged on the insulation film 114. The partition wall PI is arranged along the peripheral edges of the pixel electrode PE. The partition wall PI is formed of an organic material, such as an ultraviolet-cured resin or thermoset resin, or an inorganic material.

An organic layer ORG forming the organic EL element is arranged on the pixel electrode PE. The organic layer ORG includes at least a light-emitting layer, and may include a hole injection layer, a hole transportation layer, an electron injection layer, an electron transportation layer, and the like. Materials for the organic layer ORG may include a fluorescent material or a phosphorescent material.

An opposed electrode CE forming the organic EL element OLED is arranged on the organic layer ORG. The opposed electrode CE coats the partition wall PI, as well as the organic layer ORG. In this example, the opposed electrode CE corresponds to a cathode. The opposed electrode CE is formed of a transparent layer formed of a conductive material, such as ITO or IZO, or a semi-transparent layer formed of magnesium silver, or the like. When a micro-cavity structure is adopted, the opposed electrode CE includes a semi-transparent layer formed of magnesium silver, or the like. The opposed electrode CE extends approximately over the entire surface of the active area 102.

The organic EL element OLED shown herein is a top-emission type that emits light from the side of the sealing electrode CE.

In the peripheral area 104 of the array substrate 100, the undercoat layer 111, the gate insulation film 112, the passivation film 113, the insulation film 114, and the partition wall PI are sequentially stacked on the insulating substrate 101. The undercoat layer 111, the gate insulation film 112, the passivation film 113, the insulation film 114, and the partition wall PI extend from the active area 102 to the peripheral area 104. The partition wall PI does not need to extend in the peripheral area 104.

In the peripheral area 104 of the array substrate 100, a wiring 130, designed to supply a potential to the opposed electrode CE, is arranged on the passivation film 113. The wiring 130 may be formed by the same process as that of the source electrode S and the drain electrode D arranged in the active area 102.

A connection portion 140, designed to electrically connect the wiring 130 and the opposed electrode CE, is provided in the peripheral area 104. A contact hole CH, which penetrates up to the wiring 130, is formed in the insulating film 114 and the partition wall PI in the connection portion 140.

The opposed electrode CE extends also to the peripheral area 104, as well as the active area 102, so as to cover the contact hole CH formed in the connection portion 140 and contact the wiring 130. Thereby, the opposed electrode CE is electrically connected to the wiring 130.

The top emission type organic EL element OLED emits light via the opposed electrode CE. Accordingly, the opposed electrode CE is formed of a conductive material having light transparency. Semi-transparent conductive materials, such as ITO and IZO, which are applicable as conductive materials forming the opposed electrode CE, have relatively high resistance. Further, when a micro-cavity structure is adopted, magnesium silver, which are usable as conductive materials for forming the opposed electrode CE, have relatively high resistance, since they are formed into a very thin film, with a thickness equal to or lower than 20 nm, for example, so as to secure light transparency.

In the vicinity of the connection portion 140 that connects the opposed electrode CE and the wiring 130, currents flowing through the opposed electrode CE arranged on the entire surface of the active area 102 concentrates toward the wiring 130. Accordingly, currents are concentrated on the opposed electrode CE arranged in the vicinity of the connection portion 140, and thereby heat generation is easily caused. Furthermore, migration may occur and result in disconnection between the opposed electrode CE and the wiring 130.

In the present embodiment, a conductive layer 150 is further stacked on the opposed electrode CE in the connection portion 140. That is, three conductive layers, i.e., the wiring 130, the opposed electrode CE, and the conductive layer 150, are stacked on the connection portion 140. With this configuration, the conductive layer 150 has a sheet resistance (Ω/□) lower than that of the opposed electrode CE, and is formed of a material including metals such as silver (Ag), aluminum (Al), copper (Cu), and gold (Au).

The conductive layer 150 should desirably have a film thickness T2, which is greater than a film thickness T1 of the opposed electrode CE. For example, while the film thickness T1 of the opposed electrode CE is approximately 20 nm, the film thickness T2 of the conductive layer 150 should desirably be 100-1000 nm. It is to be noted that the film thickness T1 of the opposed electrode CE is equivalent to the height of the wiring 130, in the normal direction, that the opposed electrode CE contacts. Further, the film thickness T2 of the conductive layer 150 corresponds to the height of the normal direction on the opposed electrode CE that the conductive layer 150 contacts. The film thickness T2 of the conductive layer 150 should be as thick as possible, so as to achieve lower resistance, but should desirably be equal to or lower than 1000 nm, since formation of a thick conductive layer 150 may result in deterioration in the manufacturing yield rate.

According to the configuration of the present embodiment with the above-described configuration, currents that have passed through the opposed electrode CE throughout the active area 102 flow through the opposed electrode CE and the conductive layer 150, in the vicinity of the connection portion 140. It is thereby possible to moderate the concentration of currents in the opposed electrode CE and suppress heat generation in the opposed electrode CE. This allows disconnections between the opposed electrode and the wiring 130 to be suppressed.

In addition, since the conductive layer 150 is arranged in the peripheral area 104, the types of materials for forming the conductive layer 150, the film thickness thereof, the forming method thereof, and the layout of the connection portion 140 may be freely selected.

Next, the layout example of the conductive layer 150 will be described, with reference to plan views. In the descriptions that follow, only the structural elements necessary for the descriptions will be shown.

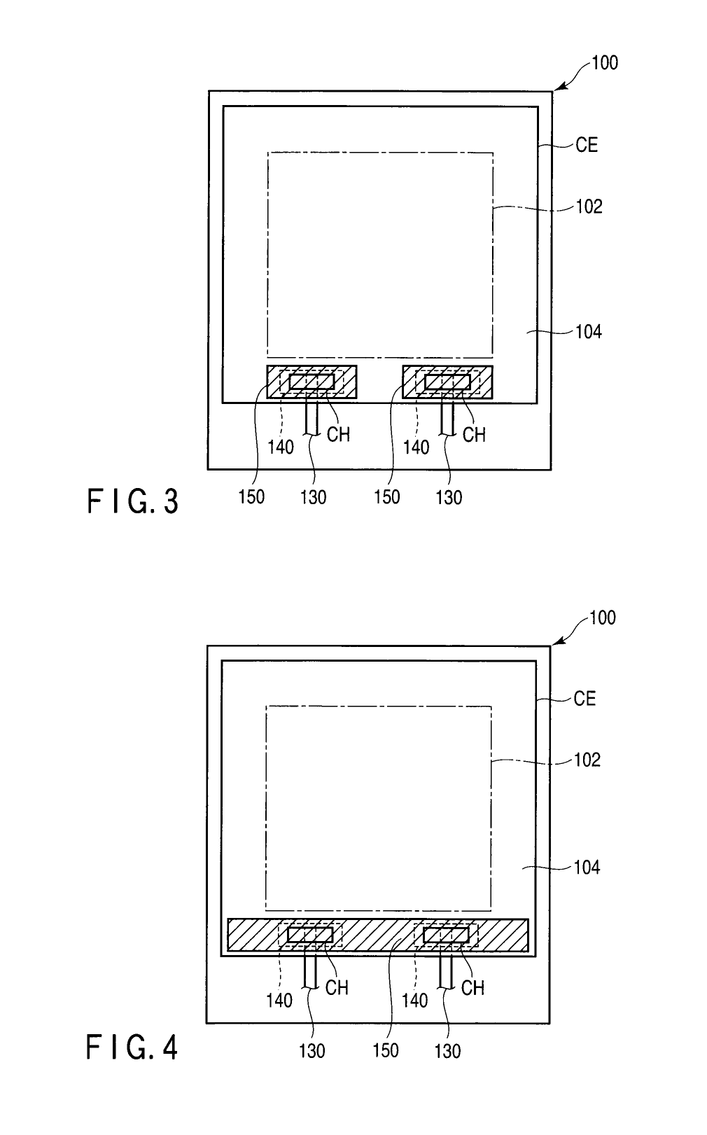

In the example shown in FIG. 3, two connection portions 140 are provided in the peripheral area 104 of the array substrate 100. The wiring 130 is arranged in the peripheral area 104 via the connection portion 140. The wirings 130 are connected to a signal supply source, not shown, and set to a predetermined potential. The contact hole CH provided in the connection portion 140 penetrates up to the wirings 130.

The opposed electrode CE extends in the peripheral area 104, as well as the active area 102. The opposed electrode CE covers the contact hole CH of the connection portion 140, and is electrically connected to the wiring 130. The conductive layer 150 is stacked on the opposed electrode CE, and is arranged in each of the two connection portions 140. In this example, since a current flows through the opposed electrode CE and the conductive layer 150, concentration of currents in the opposed electrode CE can be further moderated.

The example shown in FIG. 4 is different from the example shown in FIG. 3 in that one conductive layer 150 is formed in a linear shape that passes through two connection portions 140. In the example shown in FIG. 4, each of the wirings 130 is similarly arranged in the peripheral area 104 of the array substrate 100. The contact hole CH provided in each of the two connection portions 140 of the peripheral area 104 penetrates up to each of the wirings 130, and the opposed electrode CE and the wiring 130 are electrically connected in each of the connection portions 140. The conductive layer 150 is stacked on the opposed electrode CE in the peripheral area 104, and extends in parallel with the direction in which the two connection portions 140 are arranged. In this example, the current concentration can be further moderated than in the example shown in FIG. 3.

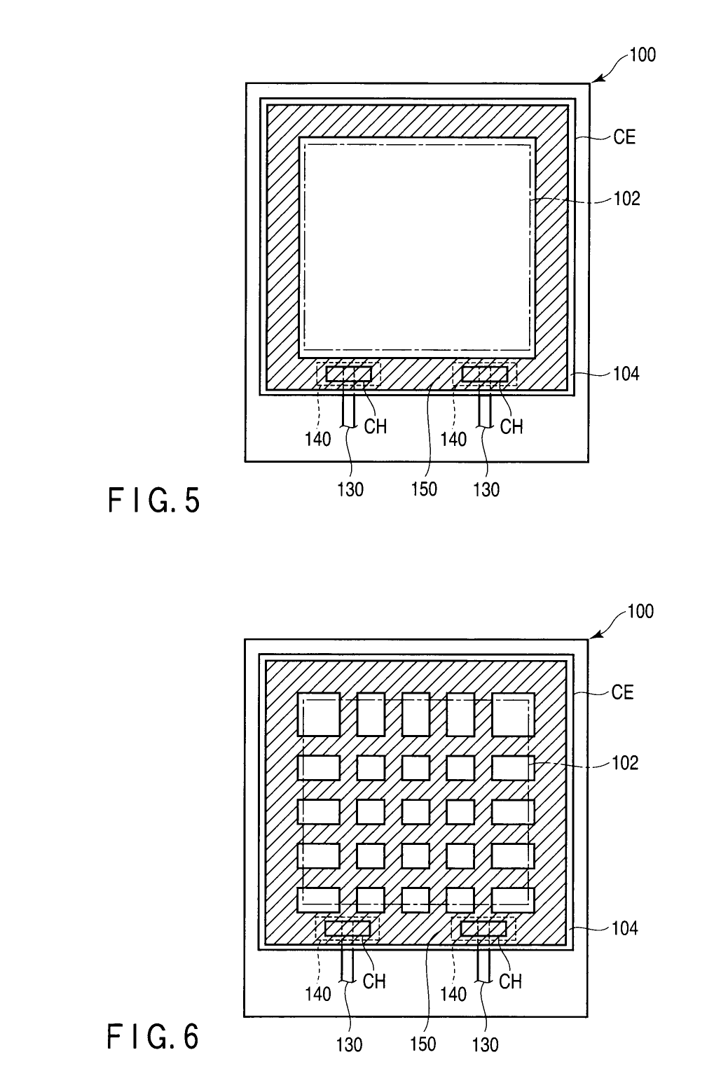

The example shown in FIG. 5 is different from the example shown in FIG. 3 in that the conductive layer 150 passes through two connection portions 140 and is formed in the shape of a frame in the peripheral area 104. In the example shown in FIG. 5, too, each of the wirings 130 is similarly arranged in the peripheral area 104 of the array substrate 100. The contact hole CH provided in each of the two connection portions 140 of the peripheral area 104 penetrates up to each of the wirings 130, and the opposed electrode CE and the wiring 130 are electrically connected in each of the connection portions 140. The conductive layer 150 is stacked on the opposed electrode CE in the peripheral area 104, and extends in the shape of a frame surrounding the active area 102. In this example, too, the current concentration in the opposed electrode CE is further moderated than in the example shown in FIG. 3.

The example shown in FIG. 6 is different from the example shown in FIG. 3 in that the conductive layer 150 passes through two connection portions 140, and is arranged in a grid pattern on the opposed electrode CE. In the example shown in FIG. 6, each of the wirings 130 is similarly arranged in the peripheral area 104 of the array substrate 100. The contact hole CH provided in each of the two connection portions 140 penetrates up to each of the wirings 130, and the opposed electrode CE and the wiring 130 are electrically connected in each of the connection portions 140.

The conductive layer 150 is stacked on the opposed electrode CE and extends in a frame shape that surrounds the active area 102 in the peripheral area 104, and is formed in a grid pattern so as to extend on a partition wall, for example, not shown, of a non-light-emitting portion in the active area 102. In this example, too, the current concentration in the opposed electrode CE can be further moderated than in the example shown in FIG. 3.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the wiring 130 has been described with regard to a case where it can be formed in the same process as that of the source electrode S, but the wiring 130 does not need to be arranged on the passivation film 113. For example, the wirings 130 may be arranged on the gate insulation film 112, and, in that case, may be formed in the same process as that of the gate G. Further, the wiring 130 may be arranged on the insulation film 114, and, in that case, may be formed in the same process as that of the pixel electrode PE.

Further, the partition wall PI and the insulation film 114 do not need to extend in the connection portion 140. When the wiring 130 is not arranged on the passivation film 113, contact with the opposed electrode CE can be provided by forming a contact hole CH that penetrates up to the wiring in various insulation films that cover the wirings.

Further, the organic EL device, which has been described as the organic EL display device in the present embodiment, may be applied to an organic EL illumination or an organic EL printer head, for example.

What is claimed is:

1. An organic EL device, comprising:
an insulating substrate;
an organic EL element including a pixel electrode arranged in an active area above the insulating substrate, an organic layer arranged on the pixel electrode, and an opposed electrode arranged on the organic layer;
a wiring arranged in a peripheral area outside the active area above the insulating substrate and electrically connected to the opposed electrode that extends from the active area to the peripheral area; and
a conductive layer formed on the opposed electrode in a connection portion that connects the wiring and the opposed electrode.

2. The organic EL device according to claim 1, wherein a sheet resistance of the conductive layer is lower than a sheet resistance of the opposed electrode.

3. The organic EL device according to claim 1, wherein the conductive layer has a film thickness greater than a film thickness of the opposed electrode.

4. The organic EL device according to claim 1, wherein the conductive layer is formed in a linear shape on the opposed electrode.

5. The organic EL device according to claim 4, wherein the wiring and the opposed electrode are connected by a plurality of connection portions, and the conductive layer is formed on the opposed electrode so as to extend over said plurality of connection portions.

6. The organic EL device according to claim 4, wherein the wiring and the opposed electrode are connected by a plurality of connection portions, and
the conductive layer is formed on the opposed electrode in each of said plurality of connection portions.

7. The organic EL device according to claim 1, wherein the conductive layer is formed in a frame shape on the opposed electrode.

8. The organic EL device according to claim 1, wherein the conductive layer is formed in a grid pattern on the opposed electrode.

9. The organic EL device according to claim 1, wherein
the pixel electrode includes a reflective electrode, and
the organic EL device is a top emission type that emits light from the side of the opposed electrode.

10. The organic EL device according to claim 1, wherein the opposed electrode is formed of a transparent conductive material or magnesium silver.

11. An organic EL device, comprising:
an insulating substrate;
a wiring arranged above the insulating substrate;
an insulating layer arranged on the wiring and including a contact hole that penetrates up to the wiring;
an organic EL element including a pixel electrode arranged above the insulating substrate, an organic layer arranged on the pixel electrode, and an opposed electrode arranged on the organic layer and the insulating layer, covering the contact hole, and electrically connected to the wiring; and
a conductive layer arranged on the opposed electrode in the contact hole.

12. The organic EL device according to claim 11, wherein a sheet resistance of the conductive layer is lower than a sheet resistance of the opposed electrode.

13. The organic EL device according to claim 11, wherein the conductive layer has a film thickness greater than a film thickness of the opposed electrode.

14. The organic EL device according to claim 11, wherein the conductive layer is formed in a linear shape on the opposed electrode.

15. The organic EL device according to claim 14, wherein the wiring and the opposed electrode are electrically connected in a plurality of contact holes, and
the conductive layer is formed on the opposed electrode in said plurality of contact holes.

16. The organic EL device according to claim 14, wherein the wiring and the opposed electrode are electrically connected in a plurality of contact holes, and
the conductive layer is formed on the opposed electrode in each of said plurality of contact holes.

17. The organic EL device according to claim 11, wherein the conductive layer is formed in a frame shape on the opposed electrode.

18. The organic EL device according to claim 11, wherein the conductive layer is formed in a grid pattern on the opposed electrode.

19. The organic EL device according to claim 11, wherein
the pixel electrode includes a reflective electrode, and
the organic EL device is a top emission type that emits light from the side of the opposed electrode.

20. The organic EL device according to claim 11, wherein the opposed electrode is formed of a transparent conductive material or magnesium silver.
